(19) United States
(12) Patent Application Publication
(10) Pub. No.: US 2026/0190641 A1
(43) Pub. Date: Jul. 2, 2026

(54) DISPLAY DEVICE

(71) Applicant: LG DISPLAY CO., LTD., SEOUL (KR)

(72) Inventors: Hyeonhye Yu, Paju-si (KR); YoungNam Lim, Paju-si (KR); SeHong Park, Paju-si (KR); SeoHyun Nam, Paju-si (KR)

(21) Appl. No.: 19/372,556

(22) Filed: Oct. 29, 2025

(30) Foreign Application Priority Data
Dec. 27, 2024 (KR) 10-2024-0199058

(51) Int. Cl. H10K 59/122; H10H 29/37; H10H 29/853; H10H 29/855; H10K 59/35; H10K 59/80; H10K 102/00

(52) U.S. Cl. CPC H10K 59/122; H10H 29/37; H10H 29/853; H10H 29/855; H10K 59/35; H10K 59/873; H10K 59/879; H10K 2102/351

(57) ABSTRACT

A display device includes a substrate on which a plurality of subpixels are disposed, an insulating layer including a depression disposed in each of the plurality of subpixels and a peripheral portion surrounding the depression, a pixel electrode disposed on the depression and the peripheral portion, a bank disposed on the pixel electrode and the insulating layer and having an opening overlapping with at least a portion of the depression, an intermediate layer disposed on the bank and on the opening of the bank, a common electrode disposed on the intermediate layer, an encapsulation layer disposed on the common electrode, and a fine notch pattern disposed in an area corresponding to the peripheral portion and disposed in the bank.

### CROSS REFERENCE TO RELATED APPLICATION

Pursuant to 35 U.S.C. § 119(a), this application claims an earlier filing date and right of priority to Korean Patent Application No. 10-2024-0199058, filed on Dec. 27, 2024 in the Korean Intellectual Property Office, the contents of which are hereby incorporated by reference in their entirety.

### TECHNICAL FIELD

The present disclosure relates to electronic devices, and more specifically, to display devices.

### BACKGROUND

In today's information society, display devices for presenting images or visual information to users are increasingly important. The need for such display devices has caused display technology to be rapidly developed, and various types of display devices, such as a liquid crystal display (LCD) device, an organic light emitting display (OLED) device, an inorganic light emitting display (ILED) device, a micro light emitting display (micro LED) device, a mini light emitting displays (mini LED) device, a quantum dot light emitting display (QLED) device, and the like, have been developed and widely used.

### SUMMARY

According to one or more example implementations of the present disclosure, a display device includes a substrate on which a plurality of subpixels are disposed, an insulating layer including a depression disposed in each of the plurality of subpixels and a peripheral portion surrounding the depression, a pixel electrode disposed on the depression and the peripheral portion, a bank disposed on the pixel electrode and the insulating layer and having an opening overlapping with at least a portion of the depression, an intermediate layer disposed on the bank and the opening of the bank, a common electrode disposed on the intermediate layer, an encapsulation layer disposed on the common electrode, and a fine notch pattern disposed in an area corresponding to the peripheral portion and disposed in the bank.

According to one or more example implementations of the present disclosure, a display device includes a substrate including a display area including at least one light emitting area and a non-display area surrounding the display area, an insulating layer located in the display area and including a depression and a peripheral portion surrounding the depression, a pixel electrode disposed on the insulating layer, a bank having an opening overlapping with at least a portion of the depression, an intermediate layer disposed on the pixel electrode and the bank, a common electrode disposed on the intermediate layer, an encapsulation layer disposed on the common electrode, and a fine notch pattern disposed in an area corresponding to the peripheral portion and disposed along the opening of the bank while being located in the bank.

### BRIEF DESCRIPTION OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and implementations described herein are not limited to the illustrations of the accompanying drawings.

FIG. 1 illustrates an example system configuration of a display device according to aspects of the present disclosure.

FIG. 2 is an example cross-sectional view of a subpixel included in a display panel according to aspects of the present disclosure.

FIG. 3 is an example plan view illustrating subpixels SP disposed in the display panel according to aspects of the present disclosure.

FIG. 4 is an example cross-sectional view taken along line A-B of FIG. 3 in the display panel according to aspects of the present disclosure.

FIGS. 5 to 7 are example cross-sectional views of area X of FIG. 4.

FIGS. 8 and 9 are example plan views of subpixels in the display panel according to aspects of the present disclosure.

FIG. 10 is an example plan view illustrating light emitting areas of a subpixel in the display panel according to aspects of the present disclosure.

FIGS. 11 and 12 illustrate example light extraction principles by the display device according to aspects of the present disclosure.

FIGS. 13 and 14 are simulation results for example light extraction paths for the display device according to aspects of the present disclosure.

### DETAILED DESCRIPTION

Display devices can have a structure of enabling light emitted from light emitting elements to emit outside of the display devices for displaying images. However, display devices can suffer from a problem in which luminance of the display devices is reduced due to a situation where light emitted from light emitting elements is trapped inside of the display devices without being emitting to the outside. Challenges can arise in improving the luminance of display devices.

One or more aspects of the present disclosure may provide a display device capable of improving light extraction efficiency.

One or more aspects of the present disclosure may provide a display device that includes a light extraction pattern disposed in a non-light emitting area, and is capable of extracting a portion of light traveling along an encapsulation layer acting as a light guide path.

One or more aspects of the present disclosure may provide a display device that includes a light extraction pattern disposed in a non-light emitting area, and is capable of blocking light produced in a subpixel from traveling toward one or more adjacent subpixels, and thereby, improving light extraction efficiency.

Aspects, examples, and implementations provided in the present disclosure are not limited to the foregoing description, and additional aspects, examples, and implementations provided in the present disclosure will become apparent to those skilled in the art from the following description.

According to one or more aspects of the present disclosure, a display device may be provided that is capable of improving light extraction efficiency.

One or more aspects of the present disclosure may provide a display device that includes a light extraction pattern disposed in a non-light emitting area, so as to be capable of extracting a portion of light traveling along an encapsulation layer acting as a light guide path.

One or more aspects of the present disclosure may provide a display device that includes a light extraction pattern disposed in a non-light emitting area, so as to be capable of blocking light produced in a subpixel from traveling toward one or more adjacent subpixels, and thereby, improving light extraction efficiency.

According to one or more aspects of the present disclosure, a display device may be provided that is capable of improving light extraction efficiency and being driven with low power consumption.

Effects or advantages from aspects, examples, and implementations described herein are not limited thereto, and additional effects or advantages will become apparent to those skilled in the art from the following description.

Reference will now be made in detail to example implementations of the present disclosure, examples or aspects of which may be illustrated in the accompanying drawings. In the following description, the structures, implementations, methods, and operations described herein are not limited to the specific examples, aspects, and implementations set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example implementations described with reference to the accompanying drawings. The present disclosure may, however, be embodied in different forms and should not be construed as limited to the example implementations set forth herein. Rather, these example implementations are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example implementations of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Terms, such as “first”, “second”, “A”, “B”, “(A)”, or “(B)” may be used herein to describe elements of the present disclosure. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts”, “overlaps with”, or the like a second element, it should be interpreted that, not only can the first element “be directly connected or coupled to”, “directly contact”, or “directly overlap with” the second element, but a third element can also be “interposed” between the first and second elements, or the first and second elements can “be connected or coupled to”, “contact”, “overlap with”, or the like each other via a fourth element. Here, the second element may be included in at least one of two or more elements that “are connected or coupled to”, “contact”, “overlap with”, or the like each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

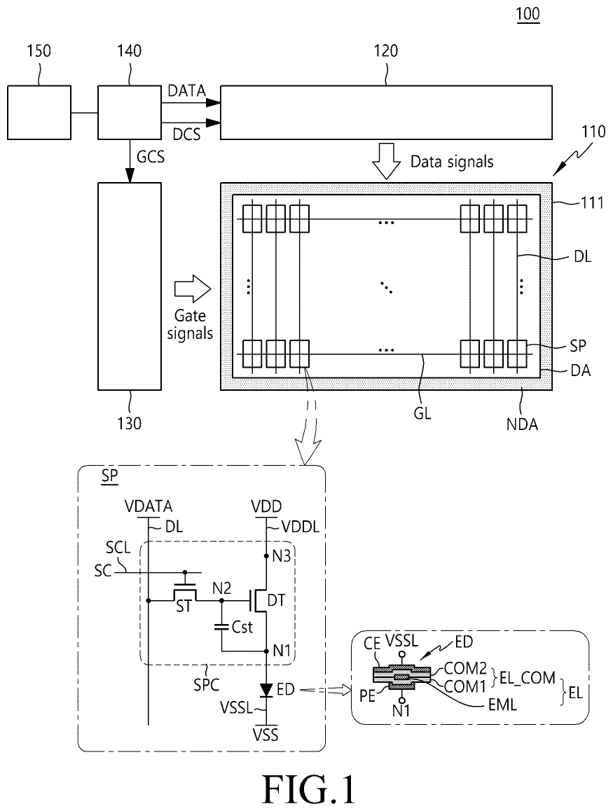

FIG. 1 illustrates an example system configuration of a display device 100 according to aspects of the present disclosure.

Referring to FIG. 1, in one or more example implementations, the display device 100 may include a display panel 110 and at least one display driving circuit, as elements for display images. The at least one display driving circuit may be a circuit for driving the display panel 110, and include a data driving circuit 120, a gate driving circuit 130, a controller 140, and other circuit components.

The display panel 110 may include a substrate 111 and a plurality of subpixels SP disposed on the substrate 111.

The substrate 111 may include a display area DA allowing an image to be displayed and a non-display area NDA located outside of the display area DA. The display area DA and the non-display area NDA may be areas defined in the display panel 110.

The display area DA may also be referred to as an active area, and a plurality of subpixels SP for displaying images may be disposed in the display area DA. The non-display area NDA may also be referred to as a non-active area and include a pad area.

In one or more aspects, the display panel 110 may be configured to have a very small non-display area NDA. The non-display area NDA may be also referred to as a “bezel” or an “bezel area.” For example, the non-display area NDA may include a first non-display area located outside of the display area DA in a first direction, a second non-display area located outside of the display area DA in a second direction, a third non-display area located outside of the display area DA in a direction opposite to the first direction, and a fourth non-display area located outside of the display area DA in a direction opposite to the second direction.

The first non-display area among the first to fourth non-display areas may include a pad area to which one or more driving circuits are connected or bonded. Among the first to fourth non-display areas, the second to fourth non-display areas may have a very small size compared to the first non-display area.

In another example, a boundary area may be defined between the display area DA and the non-display area NDA. In this example, the boundary area may be bent at a certain angle to the display area DA, and thereby, the non-display area NDA may be located under the display area DA. In this implementation, when a user views the display device 100 in front thereof, all or most of the non-display area NDA may be invisible to the user. For example, the first non-display area may include a bending area. As the bending area is bent, the first non-display area may be invisible in front of the display device 100.

Several types of signal lines for driving a plurality of subpixels SP may be disposed on the substrate 111 of the display panel 110.

In one or more aspects, the display device 100 herein may be a liquid crystal display device, or the like, or a self-emission display device in which light is emitted from the display panel 110 itself. In an example where the display device 100 is the self-emission display device, each of the plurality of subpixels SP may include a light emitting element.

For example, the display device 100 according to aspects of the present disclosure may be an organic light emitting display device in which light emitting elements are implemented using organic light emitting diodes (OLED). In another example, the display device 100 according to aspects of the present disclosure may be an inorganic light emitting display device in which light emitting elements are implemented using inorganic material-based light emitting diodes. In further another example, the display device 100 according to aspects of the present disclosure may be a quantum dot display device in which light emitting elements are implemented using quantum dots, which are self-emission semiconductor crystals.

The structure of each or at least one of a plurality of subpixels SP included in the display device 100 may depend on types of display device 100. For example, when the display device 100 is a self-emission display device including self-emission subpixels SP, each subpixel SP may include a self-emission light emitting element, one or more transistors, and one or more capacitors.

Referring to FIG. 1, each or at least one of the plurality of subpixels SP disposed in the display area DA may include a light emitting element ED and a subpixel circuit SPC configured to drive the light emitting element ED.

Referring to FIG. 1, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT for driving the light emitting element ED and a scan transistor ST configured to be turned on or off according to a scan signal SC.

The driving transistor DT can supply a driving current to the light emitting element ED.

The scan transistor ST may be configured to control an electrical state of a corresponding node in the subpixel circuit SPC or to control the state or operation of the driving transistor DT.

The at least one capacitor may include a storage capacitor Cst configured to maintain a voltage at a constant level during a display frame or a period of the display frame.

To drive one or more subpixels SP, at least one data signal VDATA, which is an image signal, and at least one scan signal SC, which is a gate signal, may be applied to the one or more subpixels SP. Further, to drive one or more subpixels SP, at least one common voltage including a first common voltage VDD and a second common voltage VSS may be applied to the one or more subpixels SP.

The light emitting element ED may include a pixel electrode PE, an intermediate layer EL, and a common electrode CE. The intermediate layer EL may be disposed between the pixel electrode PE and the common electrode CE. For example, the pixel electrode PE may be an electrode disposed in each subpixel SP, and the common electrode CE may be an electrode disposed commonly in all or some of a plurality of subpixels SP. For example, the pixel electrode PE may be an anode electrode, and the common electrode CE may be a cathode electrode. In another example, the pixel electrode PE may be a cathode electrode, and the common electrode CE may be an anode electrode. Hereinafter, for convenience of explanation, discussions may be provided based on examples where the pixel electrode PE is an anode electrode, and the common electrode CE is a cathode electrode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

In one or more aspects, the emission layer EML may be disposed for each subpixel SP, and the common intermediate layer EL_COM may be commonly disposed across all or some of a plurality of subpixels SP.

For example, the emission layer EML may be disposed for each light emitting area, and the common intermediate layer EL_COM may be commonly disposed across a plurality of light emitting areas and a non-light emitting area.

In one or more aspects, the emission layer EML and the common intermediate layer EL_COM may be commonly disposed across all or some of a plurality of subpixels SP.

For example, the emission layer EML and the common intermediate layer EL_COM may be commonly disposed across a plurality of light emitting areas and a non-light emitting area.

In one or more aspects, the first common intermediate layer COM1 may include a hole injection layer (HIL), a hole transfer layer (HTL), and the like. The second common intermediate layer COM2 may include an electron transport layer (ETL), an electron injection layer (EIL), and the like.

The hole injection layer can inject holes from the pixel electrode PE to the hole transport layer, the hole transport layer can transport holes to the emission layer EML. The electron injection layer can inject electrons from the common electrode CE to the electron transport layer, and the electron transport layer can transport electrons to the emission layer EML.

In one or more aspects, the common electrode CE may be electrically connected to a second common voltage line VSSL. A second common voltage VSS may be applied to the common electrode CE through the second common voltage line VSSL. The pixel electrode PE may be electrically connected directly or indirectly (via another transistor) to a first node N1 of the corresponding driving transistor DT of each subpixel SP.

Herein, the first common voltage VDD may also be referred to as a “high voltage” or a “driving voltage”, and the “first common voltage line VDDL” may also be referred to as a “high voltage line” or a “driving voltage line”. The second common voltage VSS may also be referred to as a “low voltage” or a “base voltage”, and the second common voltage line VSSL may also be referred to as a “low voltage line”, or a “base voltage line.

Each light emitting element ED may be configured by overlapping portion of a pixel electrode PE, an emission layer EML in an intermediate layer EL, and a common electrode CE. A corresponding light emitting area may be formed by each light emitting element ED. For example, a corresponding light emitting area of each light emitting element ED may include an area where a pixel electrode PE, an emission layer EML in an intermediate layer EL, and a common electrode CE overlap with each other.

In one or more aspects, each or at least one of a plurality of light emitting elements ED included in the display panel 110 of the display device 100 may be an organic light emitting diode (OLED), an inorganic light emitting diode (LED), a quantum dot (QD) light emitting element, a micro light emitting diode, a mini light emitting diode, or the like, but aspects of the present disclosure are not limited thereto. In the example where each or at least one of a plurality of light emitting elements ED included in the display panel 110 of the display device 100 is an organic light emitting diode (OLED), an intermediate layer EL included in the organic light emitting diode (OLED) may include an organic material.

Referring to FIG. 1, the driving transistor DT may be a transistor configured to supply a driving current to the light emitting element ED. The driving transistor DT may be connected between a first common voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A first common voltage VDD delivered through the first common voltage line VDDL may be applied to the third node N3.

In the driving transistor DT, the second node N2 may be a gate node, the first node N1 may be a source node or a drain node, and the third node N3 may be the drain node or the source node. Hereinafter, for merely convenience of explanation, discussions may be provided based on examples where the first, second, and third nodes (N1, N2, and N3) of the driving transistor DT are source, gate, and drain nodes, respectively. However, aspects of the present disclosure are not limited thereto.

The scan transistor ST included in the subpixel circuit SPC illustrated in FIG. 1 may be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located outside of the driving transistor DT, and therefore, be different from an internal capacitor such as a parasitic capacitor (e.g., a Cgs, a Cgd) that may be formed between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

As shown in FIG. 1, the subpixel circuit SPC may include two transistors (2T: DT and ST) and one capacitor (1C: Cst) (which may be referred to as a “2T1C structure”), and in some implementations, may further include one or more transistors, or further include one or more capacitors.

For example, the subpixel circuit SPC may have an 8T1C structure including 8 transistors and 1 capacitor. In another example, the subpixel circuit SPC may have an 6T2C structure including 6 transistors and 2 capacitors. In another example, the subpixel circuit SPC may have an 7T1C structure including 7 transistors and 1 capacitor. However, aspects of the present disclosure are not limited to such specific structures.

The types and number of signals supplied to a subpixel SP, and/or the types and number of lines connected to the subpixel SP may vary depending on a structure of a corresponding subpixel circuit SPC. Further, the types and number of common voltages supplied to a subpixel SP may vary depending on a structure of a corresponding subpixel circuit SPC.

The several types of signal lines may include, for example, a plurality of data lines DL for transmitting data signals (which may be referred to as data voltages or image signals), a plurality of gate lines GL for transmitting gate signals (which may be referred to as scan signals), and the like.

In one or more aspects, the plurality of data lines DL and the plurality of gate lines GL may intersect one another. Each of the plurality of data lines DL may be configured to extend in a first direction, and each of the plurality of gate lines GL may be configured to extend in a second direction. For example, the first direction may be the column direction, and the second direction may be the row direction. In another example, the first direction may be the row direction, and the second direction may be the column direction. Hereinafter, for merely convenience of explanation, discussions are provided based on examples where the first direction is the column direction and the second direction is the row direction. Hereinafter, for convenience of explanation, discussions may be provided based on examples where each of a plurality of data lines DL is disposed in the column direction, and each of a plurality of gate lines GL is disposed in the row direction, but aspects of the present disclosure are not limited thereto.

The data driving circuit 120 may be a circuit for driving a plurality of data lines DL and can output data signals to the plurality of data lines DL.

The data driving circuit 120 can receive image data DATA in digital form from the controller 140, convert the received image data DATA into data signals in analog form, and output the resulting data signals to the plurality of data lines DL.

In one or more aspects, the data driving circuit 120 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

In one or more aspects, the data driving circuit 120 may be disposed in, and/or electrically connected to, but not limited to, only one side or edge (e.g., an upper portion or a lower portion) of the display panel 110. In one or more aspects, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to an area located outside of the display area DA of the display panel 110, or be disposed in the display area DA of the display panel 110.

The gate driving circuit 130 may be a circuit for driving a plurality of gate lines GL and can supply gate signals to the plurality of gate lines GL.

The gate driving circuit 130 can receive several types of gate driving control signals GCS, and a first gate voltage corresponding to a turn-on voltage (or a turn-on level voltage) and a second gate voltage corresponding to a turn-off voltage (or a turn-off level voltage). Thereby, the gate driving circuit 130 can generate gate signals including a period with the first gate voltage and a period with the second gate voltage during a certain period of time (e.g., a period of one frame time or a sub-period of the period of one frame time), and supply the generated gate signals to the plurality of gate lines GL.

In one or more aspects, the gate driving circuit 130 included in the display device 100 may be embedded into the display panel 110 by a gate-in-panel (GIP) technique. In an example where the gate driving circuit 130 is implemented by the gate-in-panel (GIP) technology, the gate driving circuit 130 may be disposed on the substrate 111 of the display panel 110 during the manufacturing process of the display panel 110 or display device 100.

In one or more aspects, the gate driving circuit 130 may be disposed in the non-display area NDA of the display panel 110.

In one or more aspects, the gate driving circuit 130 may be disposed in the display area DA of the display panel 110. In this implementation, for example, the gate driving circuit 130 may be disposed in, and/or electrically connected to, but not limited to, a first area (e.g., a left area or a right area) of the display area DA of the display panel 110. In another example, the gate driving circuit 130 may be disposed in, and/or electrically connected to, but not limited to, a first area (e.g., a left area or a right area) and a second area (e.g., the right area or the left area) of the display area DA of the display panel 110.

Herein, the gate driving circuit 130 embedded in the display panel 110 by the gate-in-panel (GIP) technique may also be referred to as a “gate-in-panel circuit.”

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 to the data driving circuit 120 based on the input image data.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more implementations, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, aspects of the present disclosure are not limited thereto.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display device 100 may include a touch sensor, and a touch sensing circuit configured to sense the touch sensor and detect whether a touch is applied by an object such as a finger, a pen, or the like, or a location of the touch (or touch coordinates).

The touch sensing circuit may include a touch driving circuit configured to drive and sense the touch sensor and generate and output touch sensing data, and a touch controller configured to detect whether a touch is applied or a location of the touch (or touch coordinates) based on the touch sensing data.

The touch sensor may include a plurality of touch electrodes. The touch sensor may further include a plurality of touch lines for electrically connecting the plurality of touch electrodes to the touch driving circuit.

The touch sensor may be disposed outside of the display panel 110 in the form of a touch panel or may be disposed inside of the display panel 110. The touch sensor disposed outside of the display panel 110 may be referred to as an add-on type touch sensor. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes disposed on the touch panel substrate.

In the example where the touch sensor is disposed inside of the display panel 110, the touch sensor may be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing technique, each of a plurality of touch electrodes can serve as both a driving touch electrode and a sensing touch electrode. The touch driving circuit may drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes may be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit may be implemented in separate devices or in a single device. In one or more aspects, the touch driving circuit and the data driving circuit may be implemented in separate devices or in a single device.

The display device 100 may further include a power supply circuit for supplying several types of power to the display driving circuit and/or the touch sensing circuit.

In one or more aspects, the display device 100 may be a mobile terminal such as a smart phone, a tablet, or the like, or a monitor, a television (TV), or the like. Such apparatuses may be configured in various types, sizes, and shapes. The display device 100 according to aspects of the present disclosure are not limited thereto, and may include various types, sizes, and shapes configured to display information or images. a display device according to the aspects of the present disclosure may be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display devices, vehicle apparatuses, theater apparatuses, theater display devices, televisions, wallpaper apparatuses, signage apparatuses, game apparatuses, notebook computers, monitors, cameras, camcorders, and home appliances, and the like.

In one or more aspects, the display device 100 may further include an electronic device such as a camera (e.g., an image sensor), a sensor capable of detecting an object, ambient light, and the like. For example, the sensor may be a sensor capable of detecting an object or a human body by receiving light such as infrared light, ultrasonic light, ultraviolet light or the like.

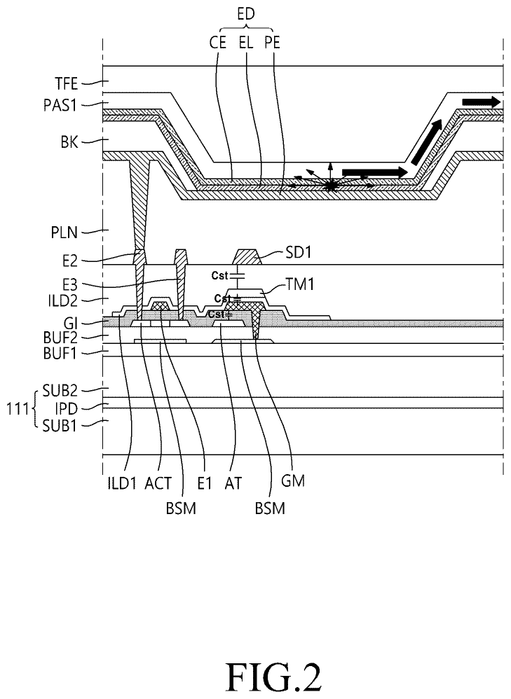

FIG. 2 is an example cross-sectional view of a subpixel SP included in the display panel 110 according to implementations of the present disclosure. In discussions that follow for the configuration of FIG. 2, discussions for features and examples identical, substantially identical, or similar to the features and examples described with reference to FIG. 1 are omitted or briefly described for convenience of description.

Referring to FIG. 2, the display area DA may include a transistor disposed on a substrate 111 and a light emitting element ED electrically connected to the transistor TR.

The transistor TR may include an active layer ACT, a gate electrode E1, a source electrode E2, and a drain electrode E3. The light emitting element ED may include a pixel electrode PE, an intermediate layer EL including an emission layer EML, and a common electrode CE.

The substrate 111 may include a first substrate SUB1 and a second substrate SUB2, and may include an intermediate layer IPD between the first substrate SUB1 and the second substrate SUB2. A first buffer layer BUF1 may be disposed on the substrate 111, and for example, include a single film or a multi-film. A light shield BSM and a second buffer layer BUF2 may be disposed on the first buffer layer BUF1

Referring to FIG. 2, an active layer ACT and a first plate AT may be disposed on the second buffer layer BUF2. A gate insulating layer GI may be disposed on the active layer ACT and the first plate AT. The gate electrode E1 and a second plate GM may be disposed on the gate insulating layer GI. A first interlayer insulating layer ILD1 may be disposed on the gate electrode E1 and the second plate GM. A third plate TM1 may be disposed on the first interlayer insulating layer ILD1. A second interlayer insulating layer ILD2 may be disposed on the third plate TM1. The source electrode E2, the drain electrode E3, and a fourth plate SD1 may be disposed on the second interlayer insulating layer ILD2. The first to fourth plates (AT, GM, TM1, and SD1) may overlap with each other and form a storage capacitor Cst.

Referring to FIG. 2, a planarization layer PLN may be disposed on the source electrode E2, the drain electrode E3, and the fourth plate SD1. The planarization layer PLN may serve to flatten a surface of the substrate 111 or one or more layers on the substrate. The planarization layer PLN may be an insulating layer including an organic insulating material or an inorganic insulating material, but aspects of the present disclosure are not limited thereto.

The planarization layer PLN may include a hole in an area overlapping with a portion of an upper surface of the source electrode E2 of the transistor.

The planarization layer PLN may have a depression exposing a portion of the upper surface of the planarization layer PLN. The planarization layer PLN may include a peripheral portion extending from the depression.

The depression may be located in a subpixel. The depression may include a flat portion, and an inclined portion extending from the flat portion and surrounding the flat portion. The flat portion of the depression may correspond to an area where the portion of the upper surface of the planarization layer PLN is exposed. The peripheral portion of the planarization layer PLN may extend from the inclined portion of the depression.

Referring to FIG. 2, the light emitting element ED including the pixel electrode PE, the intermediate layer EL, and the common electrode CE may be disposed on the planarization layer PLN.

The pixel electrode PE may be disposed on the planarization layer PLN. The pixel electrode PE may be disposed on the planarization layer PLN and overlap with the depression. The pixel electrode PE may include a flat area, which is an area where the pixel electrode PE is parallel to the surface of the substrate 111 and where the pixel electrode PE overlaps with the flat portion of the depression and the peripheral portion of the planarization layer PLN, and an inclined area, which is an area disposed on the inclined portion of the depression and having a predetermined angle with the surface of the substrate 111.

The pixel electrode PE of the light emitting element ED may include a reflective material. The pixel electrode PE may include at least one of aluminum, neodymium, nickel, titanium, tantalum, copper (Cu), silver (Ag), and an aluminum alloy, but aspects of the present disclosure are not limited thereto.

Referring to FIG. 2, in at least one subpixel area, the transistor TR may be electrically connected to the pixel electrode PE of the light emitting element ED through a contact hole penetrating the planarization layer PLN. For example, the source electrode E2 or the drain electrode E3 of the transistor TR may be electrically connected to the pixel electrode PE of the light emitting element ED through the contact hole penetrating the planarization layer PLN.

A bank BK having an opening through which the pixel electrode PE is exposed may be disposed on the depression of the planarization layer PLN. The bank BK may be disposed on a portion of the pixel electrode PE and the planarization layer PLN.

The intermediate layer EL may be disposed on the pixel electrode PE exposed by the bank BK and the bank BK. The common electrode CE may be disposed on the intermediate layer EL.

The common electrode CE may be disposed on the intermediate layer EL.

The common electrode CE may include a conductive material allowing light to be fully transmitted or to be partially transmitted. For example, the common electrode CE may include at least one of transparent conductive oxides, such as indium tin oxide (ITO), indium zinc oxide (IZO), indium tin zinc oxide (ITZO), zinc oxide, tin oxide, and the like, or include a semi-transmissive metal, such as magnesium (Mg), silver (Ag), or an alloy of Mg and Ag. For example, when the common electrode CE includes a semi-transmissive metal, a thickness of the common electrode CE may be less than that of the pixel electrode PE.

Referring to FIG. 2, in one or more aspects, in the display panel 110, at least one light emitting area EA disposed in the display area DA may include a main light emitting area and an auxiliary light emitting area. The main light emitting area may be an area corresponding to an area where the pixel electrode PE, the intermediate layer EL, and the common electrode CE are sequentially stacked and overlap with each other. The main light emitting area may be an area where light emitted from the intermediate layer EL is extracted to the outside of the display panel 110 through the opening of the bank BK. The auxiliary light emitting area may be an area where light reflected from an inclined surface is directed. For example, the auxiliary light emitting area may be an area where light emitted from the intermediate layer EL is reflected from the pixel electrode PE disposed on an inclined surface of the planarization layer PLN (e.g., a surface of the inclined portion of the depression) and extracted to the outside of the display panel 110.

Referring to FIG. 2, an encapsulation layer may be located on the common electrode CE of the light emitting element ED.

The encapsulation layer may be a layer capable of preventing moisture or oxygen from penetrating into light emitting elements ED disposed under the encapsulation layer. The encapsulation layer can prevent moisture or oxygen from penetrating into intermediate layers EL. For example, the encapsulating layer may include a single film or multi-film.

Referring to FIG. 2, the encapsulation layer may include a first encapsulation layer PAS1, a second encapsulation layer TFE, and a third encapsulation layer. The first encapsulation layer PAS1 and the third encapsulation layer may be inorganic films including an inorganic insulating material, and the second encapsulation layer TFE may be an organic film including an organic insulating material.

Since the second encapsulation layer TFE include an organic film, the second encapsulation layer TFE may also serve as a planarization layer.

Referring to FIG. 2, since the first encapsulation layer PAS1 may act as a light guide path through which light travels, a portion of light emitted from the main light emitting area may travel laterally along the first encapsulation layer PAS1 in the first encapsulation layer PAS1, which is a transparent inorganic layer. In this case, the light traveling laterally may not be reflected by the pixel electrode PE disposed in the inclined portion of the depression, resulting in being lost, or may travel to an adjacent subpixel and be mixed with light produced in the adjacent subpixel, resulting in light colors being mixed. Accordingly, there is a need for a structure capable of blocking the light guide effect provided by the encapsulating layer.

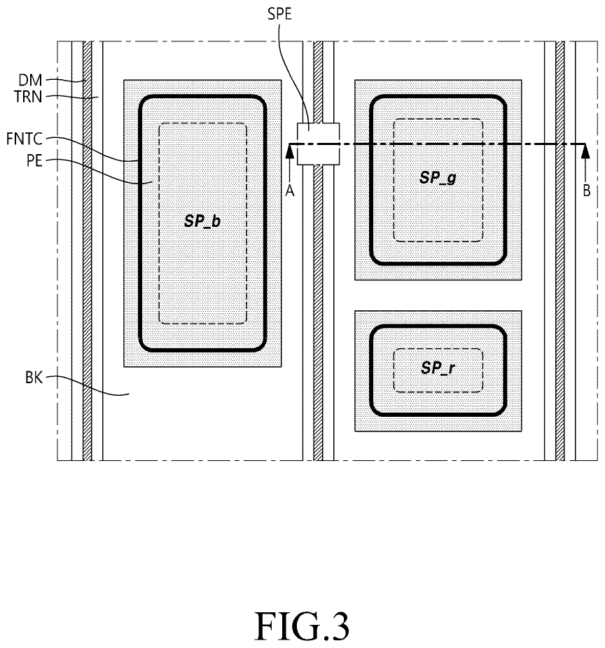

FIG. 3 is an example plan view illustrating subpixels SP disposed in the display panel 110 according to aspects of the present disclosure. In discussions that follow for the configuration of FIG. 3, discussions for features and configurations identical, substantially identical, or similar to the features and configurations described with reference to FIGS. 1 and 2 are omitted or briefly described for simplicity.

Referring to FIG. 3, in one or more example implementations, the display panel 110 may include a plurality of subpixels SP. The plurality of subpixels SP may include at least one first subpixel SP_r emitting red light, at least one second subpixel SP_g emitting green light, and at least one third subpixel SP_b emitting blue light.

Each subpixel SP may be surrounded by a bank BK. For example, the bank BK may define a corresponding area of each subpixel SP.

Referring to FIG. 3, the bank BK may include at least one trench TRN and at least one convex pattern DM in a first direction (e.g., the column direction). For example, a convex pattern DM may be disposed between a pair of trenches TRN. The convex pattern DM may be formed to protrude in the vertical direction from the substrate. The convex pattern DM may include the same material as a material included in the bank BK. As the trench TRN and the convex pattern DM are disposed on the bank BK, a lateral leakage current can be blocked from moving to an adjacent subpixel SP.

In one or more aspects, the bank BK may include at least one spacer SPE disposed between the plurality of subpixels SP. The spacer SPE may be formed to protrude in the vertical direction from the substrate. The spacer SPE may include the same material as the material of the bank BK. A height of the spacer SPE may be greater than a height of the convex pattern DM.

Referring to FIG. 3, a fine notch pattern FNTC may be disposed to overlap with an outer portion of a pixel electrode PE. The fine notch pattern FNTC may be disposed to extend along the outer portion of the pixel electrode PE, but aspects of the present disclosure are not limited thereto.

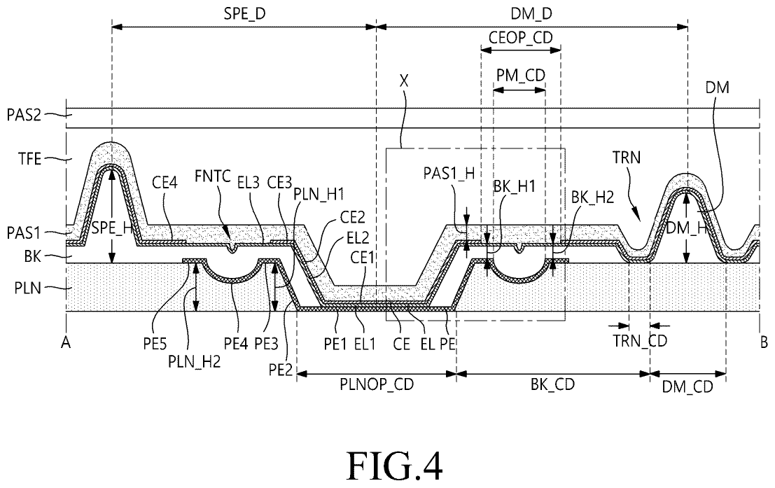

FIG. 4 is an example cross-sectional view taken along line A-B of FIG. 3 in the display panel 110 according to aspects of the present disclosure. In discussions that follow for the configuration of FIG. 4, discussions for features and configurations identical, substantially identical, or similar to the features and configurations described with reference to FIGS. 1 to 3 are omitted or briefly described for simplicity.

The cross-sectional structure of the display panel 110 shown in FIG. 4 illustrates a partial structure disposed on the planarization layer PLN in the cross-sectional structure of the display panel 110 shown in FIG. 2.

Referring to FIG. 4, in one or more example implementations, a planarization layer PLN may include an open area. The planarization layer PLN may include a depression and a peripheral portion surrounding the depression. The depression may include a flat portion and an inclined portion surrounding the flat portion. The peripheral portion may have a concave region (e.g., a region having a concave shape) that is depressed downwardly from an upper surface of the peripheral portion. For example, the concave shape of the peripheral portion may be a parabolic shape.

A pixel electrode PE may be disposed on the planarization layer PLN. The pixel electrode PE may include a first portion PE1, a second portion PE2, a third portion PE3, a fourth portion PE4, and a fifth portion PE5. The first portion PE1 of the pixel electrode PE may correspond to the flat portion of the depression. The second portion PE2 of the pixel electrode PE may correspond to the inclined portion of the depression. The fourth portion PE4 of the pixel electrode PE may correspond to the concave shape of the peripheral portion. The third portion PE3 of the pixel electrode PE may be located between the second portion PE2 and the fourth portion PE4 of the pixel electrode PE in the peripheral portion. The fifth portion PE5 of the pixel electrode PE may correspond to a portion outside of the fourth portion PE4 of the pixel electrode PE in the peripheral portion.

The bank BK may be disposed on the pixel electrode PE and the planarization layer PLN. The bank BK may be disposed to expose the pixel electrode PE in the open area PLNOP of the planarization layer PLN. The bank BK may have an opening overlapping with at least a portion of the depression. The bank BK may be disposed on at least one outer portion of the flat portion of the depression, at least one inclined portion of the depression, and the peripheral portion of the planarization layer. A thickness BK_H1 of the bank BK in the third portion PE3 of the pixel electrode PE may be greater than a thickness BK_H2 of the bank BK in the fifth portion PE5 of the pixel electrode PE. A thickness PLN_H1 of the planarization layer PLN in the third portion PE3 of the pixel electrode PE may be less than a thickness PLN_H2 of the planarization layer PLN in the fifth portion PE5 of the pixel electrode PE. The sum of respective thicknesses of the planarization layer PLN and the bank BK in the third portion PE3 of the pixel electrode PE may be substantially equal to the sum of respective thicknesses of the planarization layer PLN and the bank BK in the fifth portion PE5 of the pixel electrode PE. The bank BK may include an organic insulating material with a low refractive index. For example, the bank BK may include an organic insulating material having a refractive index n of about 1.6.

An intermediate layer EL may be disposed on the pixel electrode PE and the bank BK. The intermediate layer EL may include a first portion EL1, a second portion EL2, and a third portion EL3. The first portion EL1 of the intermediate layer EL may correspond to the first portion PE1 of the pixel electrode PE disposed in the opening of the bank BK. The second portion EL2 of the intermediate layer EL may correspond to an inclined surface of the opening of the bank BK. The third portion EL3 of the intermediate layer EL may correspond to an upper surface of the bank BK.

A common electrode CE may be disposed on the intermediate layer EL. The common electrode CE may include a first portion CE1, a second portion CE2, a third portion CE3, and a fourth portion CE4. The first portion CE1 of the common electrode CE may correspond to the first portion PE1 of the pixel electrode PE disposed in the opening of the bank BK. The second portion CE2 of the common electrode CE may correspond to the inclined surface of the opening of the bank BK. The third portion CE3 of the common electrode CE may correspond to a portion of the upper surface of the bank BK. The fourth portion CE4 of the common electrode CE may correspond to another portion of the upper surface of the bank BK spaced apart from the third portion CE3 of the common electrode CE. The common electrode CE may have an open area between the third portion CE3 and the fourth portion CE4.

Referring to FIG. 4, the fine notch pattern FNTC may be located in an area corresponding to the concave shape of the peripheral portion of the planarization layer PLN and be disposed in the bank BK. For example, the fine notch pattern FNTC may be disposed in an area overlapping with the fourth portion PE4 of the pixel electrode PE.

The fine notch pattern FNTC may be located at the focus of the concave shape of the peripheral portion. A width of the fine notch pattern FNTC may be 200 nm or more and 800 nm or less. For example, the width of the fine notch pattern FNTC may be 200 nm or more and 400 nm or less. As another example, the width of the fine notch pattern FNTC may be in the wavelength range of visible light. For example, the width of the fine notch pattern FNTC may be 380 nm or more and 780 nm or less.

The fine notch pattern FNTC may have a parabolic shape in the cross-sectional view. For example, the concave shape of the peripheral portion may be represented as y=ax² (a>0, |x|≤PM_CD/2), and the fine notch pattern FNTC may be located at (0, 1/(4a)). Here, 1/(4a)=(PM_H+BK_H1) (referring to FIGS. 4 to 7).

The fine notch pattern FNTC may be disposed not overlapping with at least a portion of the common electrode CE. For example, the width of the fine notch pattern FNTC may be less than a width CEOP_CD of the open area of the common electrode CE. For example, a width PM_CD of the concave shape of the peripheral portion may be less than the width CEOP_CD of the open area of the common electrode CE.

Referring to FIG. 4, a first encapsulating layer PAS1 may be disposed on the common electrode CE. The first encapsulating layer PAS1 may be a transparent insulating layer including an inorganic insulating material. The first encapsulating layer PAS1 may include an inorganic insulating material with a high refractive index. For example, the first encapsulating layer PAS1 may include an inorganic insulating material having a refractive index n of about 1.9.

A second encapsulating layer TFE may be disposed on the first encapsulating layer PAS1. The second encapsulating layer TFE may be a transparent insulating layer including an organic insulating material. The second encapsulating layer TFE may include an organic insulating material with a low refractive index. For example, the second encapsulating layer TFE may include an organic insulating material having a refractive index n of about 1.5.

A third encapsulating layer PAS2 may be disposed on the second encapsulating layer TFE. The third encapsulating layer PAS2 may be a transparent insulating layer including an inorganic insulating material. The third encapsulating layer PAS2 may include an inorganic insulating material with a high refractive index. For example, the third encapsulating layer PAS2 may include an inorganic insulating material having a refractive index n of about 1.9.

A portion of light emitted from a light emitting element ED may travel laterally in the first encapsulating layer PAS1, thereafter, resulting in being lost, or travel to an adjacent subpixel and be mixed with light produced in the adjacent subpixel, thereby, resulting in light colors being mixed. For example, as the first encapsulating layer PAS1 is disposed between the bank BK having a low refractive index and the second encapsulating layer TFE, light entering the first encapsulating layer PAS1 may not be totally reflected and not be extracted to the outside of the display panel 110 (for example, in a direction perpendicular to the substrate).

Accordingly, in one or more aspects, as the display panel 110 has a structure where the fine notch pattern FNTC is disposed at a point overlapping with the concave shape of the peripheral portion, light trapped in the first encapsulating layer PAS1 can be caused to travel toward a concave shape (e.g., a parabolic shape) that is the fourth portion PE4 of the pixel electrode PE, and then be reflected by the fourth portion PE4 of the pixel electrode PE and directed to exit the display panel 110.

Referring to FIG. 4, at least one trench TRN and at least one convex pattern DM may be disposed between subpixels SP. For example, a convex pattern DM may be disposed between a pair of trenches TRN. In one or more aspects, at least one spacer SPE may be disposed between subpixels SP. The spacer SPE may be disposed in one or more portions of the bank BK. A height SPE_H of the spacer SPE may be greater than a height DM_H of the convex pattern DM.

A distance SPE_D from the center of a subpixel SP to the spacer SPE and a distance DM_D from the center of the subpixel SP to the convex pattern DM may be the same, but aspects of the present disclosure are not limited thereto. The distance DM_D from the center of the subpixel SP to the convex pattern DM may be defined as the sum of half a width PLNOP_CD/2 of the open area of the planarization layer PLN, a distance BK_CD of the bank BK, a distance TRN_CD of the trench TRN, and half the width DM_CD/2 of the convex pattern DM.

Referring to FIG. 4, the fine notch pattern FNTC may have a concave shape, which is a pattern of a concave shape depressed downwardly from the upper surface of the bank BK.

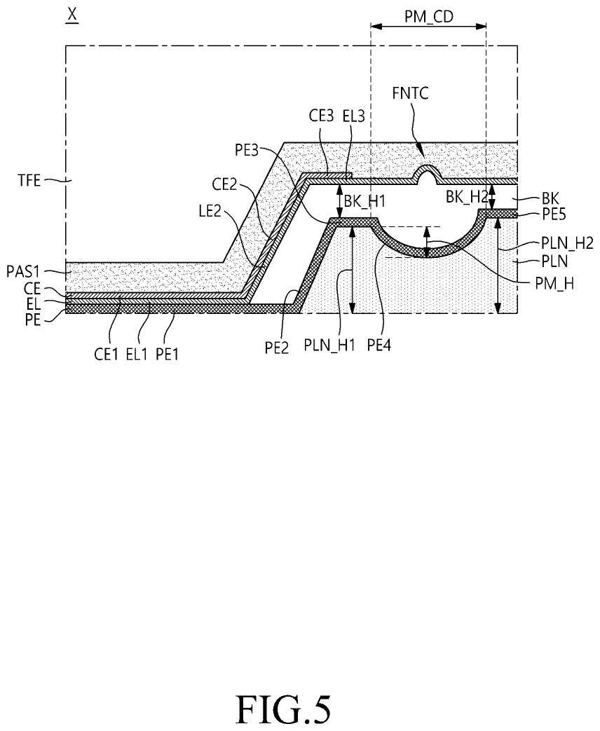

FIGS. 5 to 7 are example cross-sectional views of area X of FIG. 4. In discussions that follow for the configuration of FIGS. 5 to 7, discussions for features and configurations identical, substantially identical, or similar to the features and configurations described with reference to FIGS. 1 to 4 are omitted or briefly described for simplicity.

Referring to FIG. 5, in one or more example implementations, the fine notch pattern FNTC may be located in an area corresponding to the concave shape of the peripheral portion of the planarization layer PLN and be disposed in the bank BK. For example, the fine notch pattern FNTC may be disposed in an area overlapping with the fourth portion PE4 of the pixel electrode PE. Referring to FIG. 5, the fine notch pattern FNTC may have a convex shape, which is a pattern of a shape protruding from the upper surface of the bank BK.

A thickness BK_H1 of the bank BK in the third portion PE3 of the pixel electrode PE may be greater than a thickness BK_H2 of the bank BK in the fifth portion PE5 of the pixel electrode PE. A thickness PLN_H1 of the planarization layer PLN in the third portion PE3 of the pixel electrode PE may be less than a thickness PLN_H2 of the planarization layer PLN in the fifth portion PE5 of the pixel electrode PE. The sum of respective thicknesses of the planarization layer PLN and the bank BK in the third portion PE3 of the pixel electrode PE may be substantially equal to the sum of respective thicknesses of the planarization layer PLN and the bank BK in the fifth portion PE5 of the pixel electrode PE.

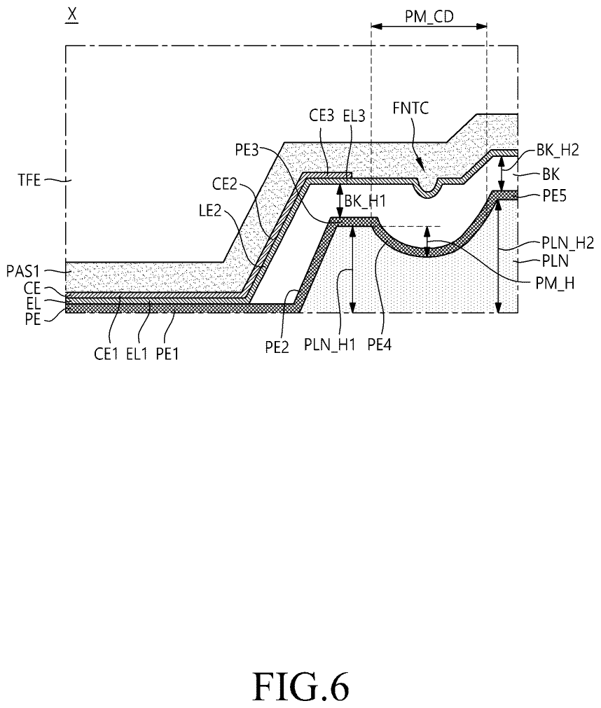

Referring to FIG. 6, in one or more example implementations, the fine notch pattern FNTC may be located in an area corresponding to the concave shape of the peripheral portion of the planarization layer PLN and be disposed in the bank BK. For example, the fine notch pattern FNTC may be disposed in an area overlapping with the fourth portion PE4 of the pixel electrode PE. The fine notch pattern FNTC may have a concave shape, which is a pattern of a concave shape depressed downwardly from the upper surface of the bank BK.

A thickness BK_H1 of the bank BK in the third portion PE3 of pixel electrode PE may be less than a thickness BK_H2 of the bank BK in the fifth portion PE5 of pixel electrode PE. A thickness PLN_H1 of planarization layer PLN in the third portion PE3 of pixel electrode PE may be less than a thickness PLN_H2 of planarization layer PLN in the fifth portion PE5 of pixel electrode PE. The sum of respective thicknesses of planarization layer PLN and bank BK in the third portion PE3 of pixel electrode PE may be smaller than the sum of respective thicknesses of planarization layer PLN and bank BK in the fifth portion PE5 of pixel electrode PE. The bank BK in the fifth portion PE5 of pixel electrode PE may be located at a higher place than the planarization layer PLN and bank BK in the third portion PE3 of pixel electrode PE.

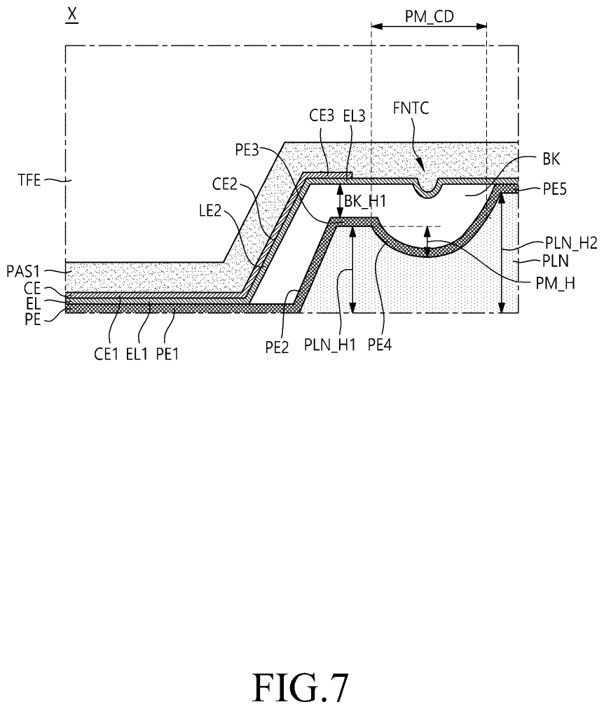

Referring to FIG. 7, in one or more example implementations, the fine notch pattern FNTC may be located in an area corresponding to the concave shape of the peripheral portion of the planarization layer PLN and be disposed in the bank BK. For example, the fine notch pattern FNTC may be disposed in an area overlapping with the fourth portion PE4 of the pixel electrode PE. The fine notch pattern FNTC may have a concave shape, which is a pattern of a concave shape depressed downwardly from the upper surface of the bank BK.

A thickness BK_H1 of the bank BK in the third portion PE3 of pixel electrode PE may be greater than a thickness BK_H2 of the bank BK in the fifth portion PE5 of pixel electrode PE. A thickness PLN_H1 of planarization layer PLN in the third portion PE3 of pixel electrode PE may be less than a thickness PLN_H2 of planarization layer PLN in the fifth portion PE5 of pixel electrode PE. The sum of respective thicknesses of planarization layer PLN and bank BK in the third portion PE3 of pixel electrode PE may be substantially the same as the sum of respective thicknesses of planarization layer PLN and bank BK in the fifth portion PE5 of pixel electrode PE. The intermediate layer EL3 and the pixel electrode PE in the third portion PE3 of the pixel electrode PE may be spaced apart from each other by the bank BK, and the intermediate layer EL3 and the pixel electrode PE in the fifth portion PE5 of the pixel electrode PE may be disposed to contact each other.

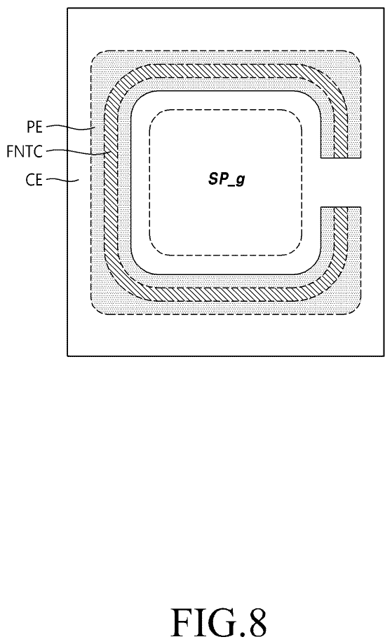

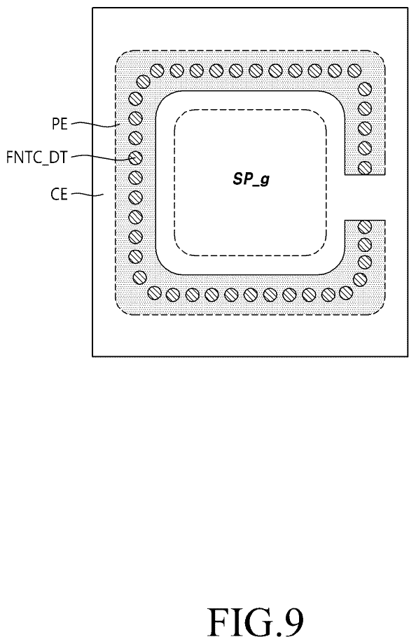

FIGS. 8 and 9 are example plan views of subpixels SP in the display panel 110 according to aspects of the present disclosure. In discussions that follow for the configuration of FIGS. 8 and 9, discussions for features and configurations identical, substantially identical, or similar to the features and configurations described with reference to FIGS. 1 to 7 are omitted or briefly described for simplicity.

Referring to FIG. 8, in one or more example implementations, a fine notch pattern FNTC may be disposed along an inner edge of a subpixel SP_g in the subpixel SP_g. The fine notch pattern FNTC may not be disposed in an area where a common electrode CE is disposed. The common electrode CE may be disposed to overlap with a pixel electrode PE. The common electrode CE may be disposed such that the common electrode CE is patterned along the fine notch pattern FNTC. The fine notch pattern FNTC and the pixel electrode PE may be exposed in an area where the common electrode CE is patterned. In this configuration, the fine notch pattern FNTC may be the fine notch pattern FNTC having a concave shape and/or a convex shape.

Referring to FIG. 9, in one or more example implementations, a fine notch pattern FNTC may be a fine dot notch pattern FNTC_DT having dot shapes or patterns. For example, the fine dot notch pattern FNTC_DT may be disposed such that dot shapes or patterns are disposed at a regular interval along an inner edge of a subpixel SP_g in the subpixel SP_g. The fine dot notch pattern FNTC_DT may not be disposed in an area where a common electrode CE is disposed. The common electrode CE may be disposed to overlap with a pixel electrode PE. The common electrode CE may be disposed to be patterned along the fine dot notch pattern FNTC_DT. The fine dot notch pattern FNTC_DT and the pixel electrode PE may be exposed in an area where the common electrode CE is patterned. In one or more aspects, a peripheral portion of the planarization layer may include concave shapes depressed downwardly from the upper surface of the peripheral portion, and the concave shapes may respectively correspond to areas overlapping with the dot patterns of the fine dot notch pattern FNTC_DT.

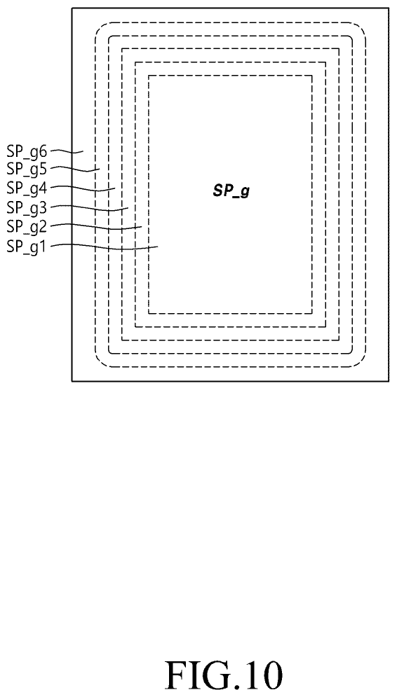

FIG. 10 is an example plan view illustrating light emitting areas of a subpixel in the display panel 110 according to aspects of the present disclosure. In discussions that follow for the configuration of FIG. 10, discussions for features and configurations identical, substantially identical, or similar to the features and configurations described with reference to FIGS. 1 to 9 are omitted or briefly described for simplicity.

Referring to FIG. 10, in one or more example implementations, a subpixel SP_g may include light emitting areas. The light emitting areas may include a first area SP_g1 located at the center of the light emitting areas, a second area SP_g2 surrounding the first area SP_g1, a third area SP_g3 surrounding the second area SP_g2, a fourth area SP_g4 surrounding the third area SP_g3, and a fifth area SP_g5 surrounding the fourth area SP_g4. The first area SP_g1, the second area SP_g2, the third area SP_g3, the fourth area SP_g4, and the fifth area SP_g5 may be connected to each other without being separated from each other.

The second area SP_g2 may be an area having lower luminance than the first area SP_g1 and the third area SP_g3. The fourth area SP_g4 may be an area having lower luminance than the third area SP_g3 and the fifth area SP_g5.

For example, the first area SP_g1 may be an area corresponding to a flat portion of a depression. The third area SP_g3 may be an area corresponding to an inclined portion of the depression. The fifth area SP_g5 may be an area corresponding to a concave shape of a peripheral portion.

The sixth area SP_g6 may be an area surrounding the light emitting areas and may be a non-light emitting area between light emitting areas.

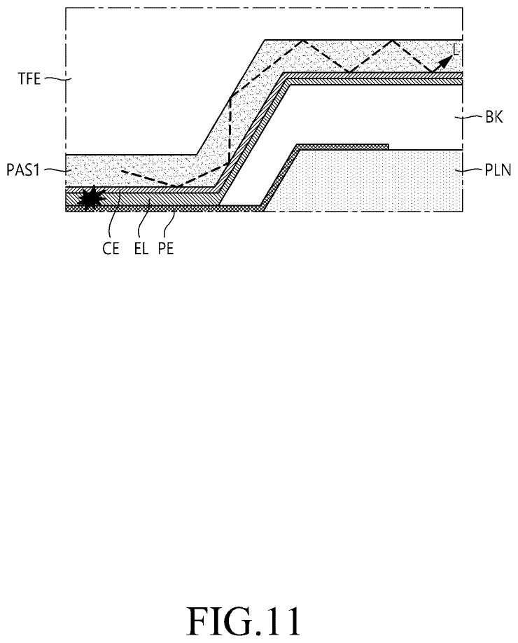

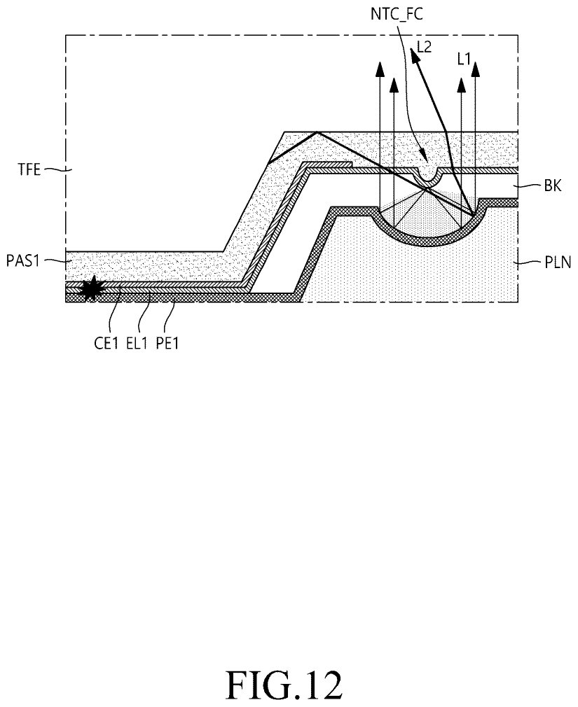

FIGS. 11 and 12 illustrate example light extraction principles by the display device 100 according to aspects of the present disclosure. In discussions that follow for the configuration of FIGS. 11 and 12, discussions for features and configurations identical, substantially identical, or similar to the features and configurations described with reference to FIGS. 1 to 10 are omitted or briefly described for simplicity.

Referring to FIG. 11, a portion of light emitted from a light emitting area may travel laterally along a first encapsulation layer PAS1 having a high refractive index in the first encapsulation layer PAS1 through a light guide path provided by the first encapsulation layer PAS1. In this case, the light L traveling laterally may not be reflected by a pixel electrode PE disposed in an inclined portion of a depression, resulting in being lost, or may travel to an adjacent subpixel and be mixed with light produced in the adjacent subpixel, resulting in light colors being mixed.

Referring to FIG. 12, a portion of light emitted from a light emitting area may travel laterally along a first encapsulation layer PAS1 having a high refractive index in the first encapsulation layer PAS1 through a light guide path provided by a first encapsulation layer PAS1. In this case, a portion of light L1 may pass through the focus NTC_FC of a notch, be reflected from a pixel electrode PE disposed in a concave shape of a peripheral portion, and then, be extracted to the front of the display panel 110. Further, another portion of light L2 may not pass through the focus NTC_FC of the notch, but be reflected from the pixel electrode PE disposed in the concave shape of the peripheral portion and be extracted to the front of the display panel 110 or in a viewing angle direction.

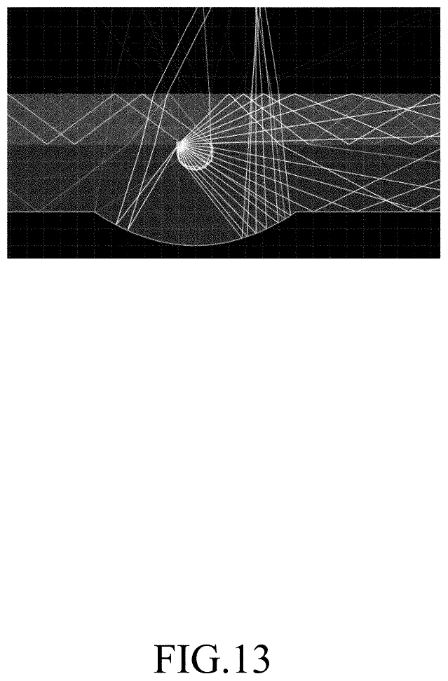

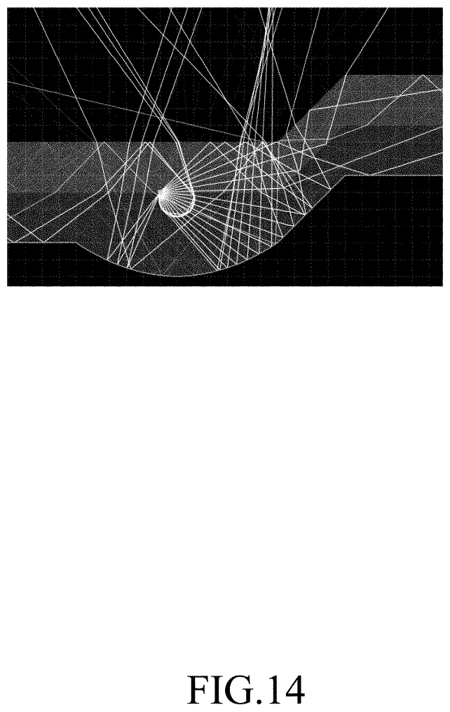

FIGS. 13 and 14 are simulation results for example light extraction paths for the display device 100 according to aspects of the present disclosure. In discussions that follow for the configuration of FIGS. 13 and 14, discussions for features and configurations identical, substantially identical, or similar to the features and configurations described with reference to FIGS. 1 to 12 are omitted or briefly described for simplicity.

Referring to FIGS. 13 and 14, it can be seen that, light traveling through a first encapsulation layer passes through the focus NTC_FC of a notch, and is reflected from a pixel electrode PE disposed in a concave shape of a peripheral portion, and then is extracted to the outside of the display panel 110.

The examples, aspects, and implementations for the display device 100 and the display panel 110 described herein may be described as follows.

According to the one or more example implementations described herein, a display device can be provided that includes a substrate on which a plurality of subpixels are disposed, an insulating layer including a depression disposed in each of the plurality of subpixels and a peripheral portion surrounding the depression, a pixel electrode disposed on the depression and the peripheral portion, a bank disposed on the pixel electrode and the insulating layer and having an opening overlapping with at least a portion of the depression, an intermediate layer disposed on the bank and the opening of the bank, a common electrode disposed on the intermediate layer, an encapsulation layer disposed on the common electrode, and a fine notch pattern disposed in an area corresponding to the peripheral portion and disposed in the bank.

In one or more aspects, the peripheral portion may include a concave shape depressed downwardly from an upper surface of the peripheral portion in an area overlapping with the fine notch pattern.

In one or more aspects, the pixel electrode may be disposed to extend to the concave shape of the peripheral portion.

In one or more aspects, each of the fine notch pattern and the concave shape of the peripheral portion may have a parabolic shape in a cross-sectional view, and the fine notch pattern may be located at a focus of the concave shape of the peripheral portion.

In one or more aspects, a thickness of the bank located between an inclined portion of the depression and the concave shape of the peripheral portion may be greater than a thickness of the bank located outside of the concave shape of the peripheral portion.

In one or more aspects, a portion of the bank located between an inclined portion of the depression and the concave shape of the peripheral portion may be located at a higher place with respect to the substrate than a portion of the bank located outside of the concave shape of the peripheral portion.

In one or more aspects, respective portions of the intermediate layer and the pixel electrode, which are located between an inclined portion of the depression and the concave shape of the peripheral portion, may be spaced apart from each other by the bank, and respective portions of the intermediate layer and the pixel electrode, which are located outside of the concave shape of the peripheral portion, may contact each other.

In one or more aspects, each of the plurality of subpixels may include light emitting area, and the light emitting area may include a first area located at a center of the light emitting area, a second area surrounding the first area, and a third area surrounding the second area. In one or more aspects, the second area may be an area presenting luminance lower than the first area and the third area.

In one or more aspects, the light emitting area may further include a fourth area surrounding the third area, and a fifth area surrounding the fourth area, and the fourth area may be an area presenting luminance lower than the third area and the fifth area.

In one or more aspects, the first area, the second area, the third area, the fourth area, and the fifth area may be connected to each other without being separated from each other.

In one or more aspects, the first area may be an area corresponding to a flat portion of the depression.

In one or more aspects, the third area may be an area corresponding to an inclined portion of the depression.

In one or more aspects, the fifth area may be an area corresponding to the concave shape of the peripheral portion.

In one or more aspects, the fine notch pattern may have a parabolic shape in a cross-sectional view, and a width of the fine notch pattern may correspond to the wavelength range of visible light.

In one or more aspects, the fine notch pattern may include a pattern having a concave shape depressed downwardly from an upper surface of the bank.

In one or more aspects, the fine notch pattern may include a pattern having a shape protruding from an upper surface of the bank.

In one or more aspects, the fine notch pattern may further include a pattern having a shape protruding from the upper surface of the bank.

In one or more aspects, at least a portion of the common electrode may be disposed not to overlap with the fine notch pattern.

In one or more aspects, the fine notch pattern may be disposed to extend along the opening of the bank.

In one or more aspects, the fine notch pattern may be disposed along the opening of the bank, and include a plurality of dot patterns arranged at equal intervals.

In one or more aspects, the peripheral portion may include concave shapes depressed downwardly from an upper surface of the peripheral portion to correspond to respective areas overlapping with the dot patterns of the fine notch pattern.

In one or more aspects, the bank may include at least one trench disposed between the plurality of subpixels.

In one or more aspects, the bank may include at least one convex pattern disposed between the plurality of subpixels and disposed adjacent to the trench.

In one or more aspects, the bank may include at least one spacer disposed between the plurality of subpixels, and a height of the spacer may be greater than a height of the convex pattern.

In one or more aspects, the encapsulation layer may include a first encapsulation layer, a second encapsulation layer on the first encapsulation layer, and a third encapsulation layer on the second encapsulation layer. In one or more aspects, a refractive index of the first encapsulation layer may be greater than refractive indices of the bank and the second encapsulation layer.

According to the one or more example implementations described herein, a display device can be provided that includes a substrate including a display area including at least one light emitting area and a non-display area surrounding the display area, an insulating layer located in the display area and including a depression and a peripheral portion surrounding the depression, a pixel electrode disposed on the insulating layer, a bank having an opening overlapping with at least a portion of the depression, an intermediate layer disposed on the pixel electrode and the bank, a common electrode disposed on the intermediate layer, an encapsulation layer disposed on the common electrode, and a fine notch pattern disposed in an area corresponding to the peripheral portion and disposed along the opening of the bank while being located in the bank.

In one or more aspects, the peripheral portion may include a concave shape depressed downwardly from an upper surface of the peripheral portion in an area overlapping with the fine notch pattern.

In one or more aspects, the pixel electrode may be disposed to extend to the concave shape of the peripheral portion.

In one or more aspects, each of the fine notch pattern and the concave shape of the peripheral portion may have a parabolic shape in a cross-sectional view, and the fine notch pattern may be located at a focus of the concave shape of the peripheral portion.

According to one or more aspects of the present disclosure, a display device may be provided that is capable of improving light extraction efficiency.

One or more aspects of the present disclosure may provide a display device that includes a light extraction pattern disposed in a non-light emitting area, and is capable of extracting a portion of light traveling along an encapsulation layer acting as a light guide path.

One or more aspects of the present disclosure may provide a display device that includes a light extraction pattern disposed in a non-light emitting area, and is capable of blocking light produced in a subpixel from traveling toward one or more adjacent subpixels, and thereby, improving light extraction efficiency.

The above description has been presented to enable any person skilled in the art to make and use the technical idea of the present disclosure, and has been provided in the context of a particular application and its requirements. Various modifications, additions and substitutions to the described implementations will be readily apparent to those skilled in the art, and the principles described herein may be applied to other implementations and applications without departing from the scope of the present disclosure. The above description and the accompanying drawings provide an example of the technical idea of the present disclosure for illustrative purposes only. That is, the disclosed implementations are intended to illustrate the scope of the technical idea of the present disclosure.

What is claimed is:

1. A display device comprising:
a substrate on which a plurality of subpixels are disposed;
an insulating layer comprising a depression disposed in each of the plurality of subpixels and a peripheral portion surrounding the depression;
a pixel electrode disposed on the depression and the peripheral portion;
a bank disposed on the pixel electrode and the insulating layer and having an opening overlapping with at least a portion of the depression;
an intermediate layer disposed on the bank and on the opening of the bank;
a common electrode disposed on the intermediate layer;
an encapsulation layer disposed on the common electrode; and
a fine notch pattern disposed in an area corresponding to the peripheral portion and disposed in the bank.

2. The display device of claim 1, wherein the peripheral portion comprises a concave region depressed downwardly from an upper surface of the peripheral portion in an area overlapping with the fine notch pattern.

3. The display device of claim 2, wherein the pixel electrode is disposed to extend to the concave region of the peripheral portion.

4. The display device of claim 3, wherein each of the fine notch pattern and the concave region of the peripheral portion has a parabolic shape in a cross-sectional view, and
wherein the fine notch pattern is located at a focus of the concave region of the peripheral portion.

5. The display device of claim 4, wherein a thickness of the bank located between an inclined portion of the depression and the concave region of the peripheral portion is greater than a thickness of the bank located outside of the concave region of the peripheral portion.

6. The display device of claim 4, wherein a portion of the bank located between an inclined portion of the depression and the concave region of the peripheral portion is located at a higher place with respect to the substrate than a portion of the bank located outside of the concave region of the peripheral portion.

7. The display device of claim 4, wherein respective portions of the intermediate layer and the pixel electrode, which are located between an inclined portion of the depression and the concave region of the peripheral portion, are spaced apart from each other by the bank, and respective portions of the intermediate layer and the pixel electrode, which are located outside of the concave region of the peripheral portion, contact each other.

8. The display device of claim 2, wherein each of the plurality of subpixels comprises a light emitting area, and the light emitting area comprises a first area located at a center of the light emitting area, a second area surrounding the first area, and a third area surrounding the second area, and
wherein the second area is an area configured with a luminance that is lower than that of the first area and the third area.

9. The display device of claim 8, wherein the light emitting area further comprises a fourth area surrounding the third area, and a fifth area surrounding the fourth area, and
wherein the fourth area is an area configured with a luminance that is lower than that of the third area and the fifth area.

10. The display device of claim 9, wherein the first area, the second area, the third area, the fourth area, and the fifth area are connected to each other without being separated from each other.

11. The display device of claim 9, wherein the first area is an area corresponding to a flat portion of the depression.

12. The display device of claim 9, wherein the third area is an area corresponding to an inclined portion of the depression.

13. The display device of claim 9, wherein the fifth area is an area corresponding to the concave region of the peripheral portion.

14. The display device of claim 1, wherein the fine notch pattern has a parabolic shape in a cross-sectional view, and a width of the fine notch pattern corresponds to a wavelength range of visible light.

15. The display device of claim 1, wherein the fine notch pattern comprises a pattern having a concave shape depressed downwardly from an upper surface of the bank.

16. The display device of claim 1, wherein the fine notch pattern comprises a pattern having a shape protruding from an upper surface of the bank.

17. The display device of claim 15, wherein the fine notch pattern further comprises a pattern having a shape protruding from the upper surface of the bank.

18. The display device of claim 1, wherein at least a portion of the common electrode is disposed not to overlap with the fine notch pattern.

19. The display device of claim 1, wherein the fine notch pattern is disposed to extend along the opening of the bank.

20. The display device of claim 1, wherein the fine notch pattern is disposed along the opening of the bank, and comprises a plurality of dot patterns arranged at equal intervals.

21. The display device of claim 20, wherein the peripheral portion comprises concave shapes depressed downwardly from an upper surface of the peripheral portion to correspond to respective areas overlapping with the dot patterns of the fine notch pattern.

22. The display device of claim 1, wherein the bank comprises at least one trench disposed between the plurality of subpixels.

23. The display device of claim 22, wherein the bank comprises at least one convex pattern disposed between the plurality of subpixels and disposed adjacent to the trench.

24. The display device of claim 23, wherein the bank comprises at least one spacer disposed between the plurality of subpixels, and a height of the spacer is greater than a height of the convex pattern.

25. The display device of claim 1, wherein the encapsulation layer comprises a first encapsulation layer, a second encapsulation layer on the first encapsulation layer, and a third encapsulation layer on the second encapsulation layer, and
wherein a refractive index of the first encapsulation layer is greater than refractive indices of the bank and the second encapsulation layer.

26. A display device comprising:
a substrate comprising a display area comprising at least one light emitting area and a non-display area surrounding the display area;
an insulating layer located in the display area and comprising a depression and a peripheral portion surrounding the depression;
a pixel electrode disposed on the insulating layer;
a bank having an opening overlapping with at least a portion of the depression;
an intermediate layer disposed on the pixel electrode and the bank;
a common electrode disposed on the intermediate layer;
an encapsulation layer disposed on the common electrode; and
a fine notch pattern disposed in an area corresponding to the peripheral portion and disposed in the bank along the opening of the bank.

27. The display device of claim 26, wherein the peripheral portion comprises a concave region depressed downwardly from an upper surface of the peripheral portion in an area overlapping with the fine notch pattern.

28. The display device of claim 27, wherein the pixel electrode is disposed to extend to the concave region of the peripheral portion.

29. The display device of claim 28, wherein each of the fine notch pattern and the concave region of the peripheral portion has a parabolic shape in a cross-sectional view, and
wherein the fine notch pattern is located at a focus of the concave region of the peripheral portion.
